(19) United States
(12) Patent Application Publication
(10) Pub. No.: US 2015/0311046 A1
(43) Pub. Date: Oct. 29, 2015

(54) FABRICATING LOW-DEFECT RARE-EARTH DOPED PIEZOELECTRIC LAYER

(71) Applicant: Avago Technologies General IP (Singapore) Pte. Ltd., Singapore (SG)

(72) Inventors: Tangshiun Yeh, Fort Collins, CO (US); Phil Nikkel, Loveland, CO (US); Kevin J. Grannen, Thornton, CO (US); Chris Feng, Fort Collins, CO (US); John Choy, Westminster, CO (US)

(73) Assignee: Avago Technologies General IP (Singapore) Pte. Ltd., Singapore (SG)

(21) Appl. No.: 14/262,785

(22) Filed: Apr. 27, 2014

(51) Int. Cl. H01J 37/34; C23C 14/14; C23C 14/35

(52) U.S. Cl. CPC H01J 37/3405; C23C 14/35; C23C 14/14; H01J 2237/3323

(57) ABSTRACT

A plasma vapor deposition (PVD) system and method for depositing a piezoelectric layer over a substrate are disclosed. A plasma is created in a reaction chamber creates from the sputtering gas supplied to the reaction chamber. The plasma sputters atoms from the sputtering target, which are deposited on the substrate for forming the thin film of the material.

### BACKGROUND

Transducers generally convert electrical signals to mechanical signals or vibrations, and/or mechanical signals or vibrations to electrical signals. Acoustic transducers, in particular, convert electrical signals to acoustic signals (sound waves) and convert received acoustic waves to electrical signals via inverse and direct piezoelectric effect. Acoustic transducers generally include acoustic resonators, such as surface acoustic wave (SAW) resonators and bulk acoustic wave (BAW) resonators, and may be used in a wide variety of electronic applications, such as cellular telephones, personal digital assistants (PDAs), electronic gaming devices, laptop computers and other portable communications devices. For example, BAW resonators include thin film bulk acoustic resonators (FBARs), which include acoustic stacks formed over a substrate cavity, and solidly mounted resonators (SMRs), which include acoustic stacks formed over an acoustic reflector (e.g., Bragg mirror). The BAW resonators may be used for electrical filters and voltage transformers, for example.

Generally, an acoustic resonator has a layer of piezoelectric material between two conductive plates (electrodes), which may be formed on a thin membrane. The piezoelectric material may be a thin film of various materials, such as aluminum nitride (AlN), zinc oxide (ZnO), or lead zirconate titanate (PZT), for example. Piezoelectric thin films made of AlN are advantageous since they generally maintain piezoelectric properties at high temperature (e.g., above 400° C.). However, AlN has a lower piezoelectric coupling coefficient d₃₃ and a lower electromechanical coupling coefficient kt² than both ZnO and PZT, for example.

An AlN thin film may he deposited with various specific crystal orientations, including a wurtzite (0001) B4 structure, which consists of a hexagonal crystal structure with alternating layers of aluminum (Al) and nitrogen (N), and a zincblend structure, which consists of a symmetric structure of Al and N atoms, for example. FIG. 1 is a perspective view of an illustrative model of the common wurtzite structure. Due to the nature of the Al—N bonding in the wurtzite structure, electric field polarization is present in the AlN crystal, resulting in the piezoelectric properties of the AlN thin film. To exploit this polarization and the corresponding piezoelectric effect, one must synthesize the AlN with a specific crystal orientation.

Referring to FIG. 1, the a-axis and the b-axis are in the plane of the hexagon at the top, while the c-axis is parallel to the sides of the crystal structure. For AlN, the piezoelectric coefficient d₃₃, along the c-axis is about 3.9 pm/V and the electromechanical coupling coefficient kt² is about 6.0, for example. Generally, higher piezoelectric coupling coefficient d₃₃ and electromechanical coupling coefficient kt² are desirable, since less material is required to provide the same piezoelectric effect. In order to improve the value of the piezoelectric coefficient d₃₃ and/or the electromechanical coupling coefficient kt², some of the Al atoms may be replaced with a different metallic element, which may be referred to as “doping.” For example, past efforts included disturbing the stoichiometric purity of the AlN crystal lattice by adding a rare earth element, such as scandium (Sc) (e.g., in amounts greater than 0.5 atomic percent) or erbium (Er) in amounts less than 1.5 atomic percent) in place of some Al atoms, but not both.

Known methods of fabricating rare-earth element doped AlN piezoelectric materials lead to certain undesirable characteristics in the resultant rare-earth element doped AlN piezoelectric material. For example, rare-earth element doped AlN piezoelectric materials fabricated using known methods and apparatuses are comparatively low textured/poor quality piezoelectric materials, having comparatively high defect densities and particulate materials in or on the rare-earth element doped AlN piezoelectric material. Additionally, rare-earth element doped AlN piezoelectric materials fabricated using known methods and apparatuses often have unacceptable variation in the tensile stress across the piezoelectric layer that results in non-uniformity in the electromechanical coupling coefficient kt² across the piezoelectric layer.

What are needed, therefore, are a method and apparatus for fabricating rare-earth element doped AlN piezoelectric materials that overcome at least the drawbacks of known methods and apparatuses described above.

### BRIEF DESCRIPTION OF THE DRAWINGS

The illustrative embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1 is a perspective view of an illustrative model a crystal structure of aluminum nitride (AlN).

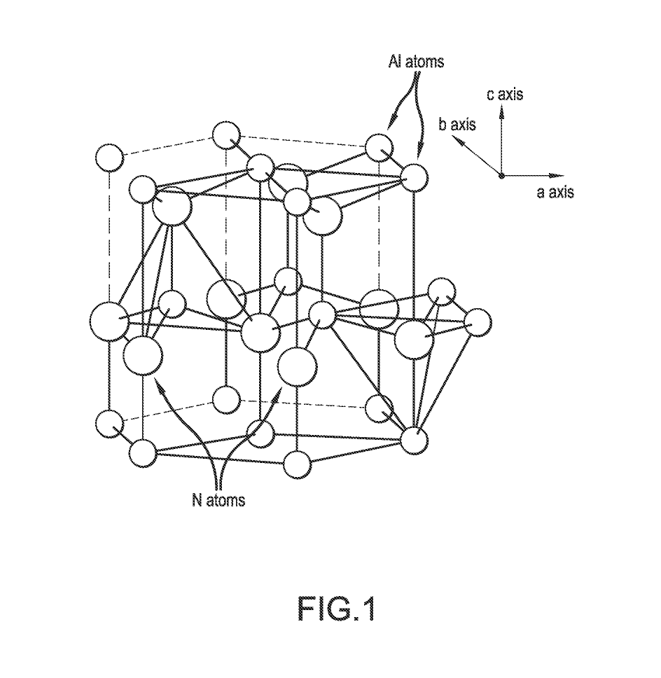

FIG. 2 is a simplified block diagram of a plasma vapor deposition (PVD) system configured to deposit a thin film of a material on a substrate, according to a representative embodiment.

FIG. 3 is a cross-sectional view of a magnet system for use in a PVD system for depositing a thin film of a material on a substrate, according to a representative embodiment.

FIG. 4 is a flow diagram showing a method of sputtering material over a substrate, according to a representative embodiment.

FIG. 5 is a table comparing various characteristics of a piezoelectric layer deposited on a substrate according to representative embodiments, with a known piezoelectric layer.

### DETAILED DESCRIPTION

It is to be understood that the terminology used herein is for purposes of describing particular embodiments only, and is not intended to be limiting. The defined terms are in addition to the technical and scientific meanings of the defined terms as commonly understood and accepted in the technical field of the present teachings.

As used in the specification and appended claims, the terms “a”, “an” and “the” include both singular and plural referents, unless the context clearly dictates otherwise. Thus, for example, “a device” includes one device and plural devices. As used in the specification and appended claims, and in addition to their ordinary meanings, the terms “substantial” or “substantially” mean to within acceptable limits or degree. For example, “substantially cancelled” means that one skilled in the art would consider the cancellation to be acceptable. As used in the specification and the appended claims and in addition to its ordinary meaning, the term “approximately” or “about” means to within an acceptable limit or amount to one having ordinary skill in the art. For example, “approximately the same” means that one of ordinary skill in the art would consider the items being compared to be the same.

In the following detailed description, for purposes of explanation and not limitation, specific details are set forth in order to provide a thorough understanding of illustrative embodiments according to the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparatuses and methods may be omitted so as to not obscure the description of the illustrative embodiments. Such methods and apparatuses are clearly within the scope of the present teachings.

Generally, it is understood that the drawings and the various elements depicted therein are not drawn to scale. Further, relative terms, such as “above,” “below,” “top,” “bottom,” “upper” and “tower” are used to describe the various elements' relationships to one another, as illustrated in the accompanying drawings. It is understood that these relative terms are intended to encompass different orientations of the device and/or elements in addition to the orientation depicted in the drawings. For example, if the device were inverted with respect to the view in the drawings, an element described as “above” another element, for example, would now be below that element.

Aspects of the present teachings are relevant to components of BAW resonator devices and filters, their materials and their methods of fabrication. Various details of such devices and corresponding methods of fabrication may be found, for example, in one or more of the following U.S. patent publications: U.S. Pat. No. 6,107,721, to Lakin; U.S. Pat. Nos. 5,587,620, 5,873,153, 6,507,983, 7,388,454, 7,629,865, 7,714,684 to Ruby et al.; U.S. Pat. Nos. 7,791,434 and 8,188,810, to Fazzio, et al.; U.S. Pat. No. 7,280,007 to Feng et al.; U.S. Pat. No. 8,248,185 to Choy, et al.; U.S. Pat. No. 7,345, 410 to Grannen, et al.; U.S. Pat. No. 6,828,713 to Bradley, et al.; U.S. Patent Application Publication 20120326807 to Choy, et al.; U.S. Patent Application Publication 201100327994 to Choy, et al.; U.S. Patent Application Publications 20110180391 and 20120177816 to Larson III et al.; U.S. Patent Application Pub. No. 20070205850 to Jamneala et al.; U.S. patent application Ser. No. 14/161,564 entitled: “Method of Fabricating Rare-Earth Element Doped Piezoelectric Material with Various Amounts of Dopants and a Selected C-Axis Orientation,” filed Jan. 22, 2014 to John L. Larson III; U.S. patent application Ser. No.: 13/662,460 entitled “Bulk Acoustic Wave Resonator having Piezoelectric Layer with Multiple Dopants,” filed on Oct. 27, 2012 to Choy, et al.; and U.S. patent application Ser. No.: 13/906,873 entitled “Bulk Acoustic Wave Resonator having Piezoelectric Layer with Varying Amounts of Dopants” to John Choy, et al. and filed May 31, 2013. The entire disclosure of each of the patents, published patent applications and patent applications listed above are hereby specifically incorporated by reference herein. It is emphasized that the components, materials and methods of fabrication described in these patents and patent applications are representative and other methods of fabrication and materials within the purview of one of ordinary skill in the art are also contemplated.

The described embodiments relate generally to methods and apparatuses for fabricating to bulk acoustic wave (BAW) resonators. The BAW resonators of the present teachings comprise one or more piezoelectric layers fabricated using the methods and apparatuses described herein. Typically, the BAW resonators comprise a first electrode; a second electrode; and a piezoelectric layer disposed between the first and second electrodes. The piezoelectric layer comprises a piezoelectric material doped with at least one rare earth element. By incorporating specific atomic percentages of a rare earth element into the piezoelectric layer, the piezoelectric properties of the piezoelectric material, including piezoelectric coefficient d₃₃ and electromechanical coupling coefficient kt², are improved as compared to the same piezoelectric material that is entirely stoichiometric (i.e., undoped).

Generally, according to various embodiments, a plasma vapor deposition (PVD) system is used to deposit a piezoelectric layer over a substrate. The PVD system comprises: a reaction chamber configured to contain the substrate, a sputtering target, a sputtering gas and a plasma; and a magnet system positioned adjacent the sputtering target and configured to generate a magnetic field in the reaction chamber. The magnet system is configured to generate a magnetic field pattern having a greater magnetic flux density at outer portions of the magnet system than at an inner portion of the magnet system. The plasma sputters atoms from the sputtering target, which are deposited on the substrate for forming the piezoelectric layer.

According to another representative embodiment, a method for depositing a piezoelectric layer over a substrate using sputter deposition is disclosed. The method comprises providing the substrate and a sputtering target in a reaction chamber of a plasma vapor deposition (PVD) system. The sputtering target comprises aluminum and at least one rare earth element. The method also comprises generating a magnetic field in the reaction chamber using a magnet system positioned adjacent to the sputtering target. The magnetic field pattern has a greater magnetic flux density at outer portions of the magnet system than at an inner portion of the magnet system. The method also comprises injecting a sputtering gas into the reaction chamber and forming a plasma from the sputtering gas in the reaction chamber. The plasma sputters atoms from the sputtering target, which are deposited on the substrate for forming the thin film of the material.

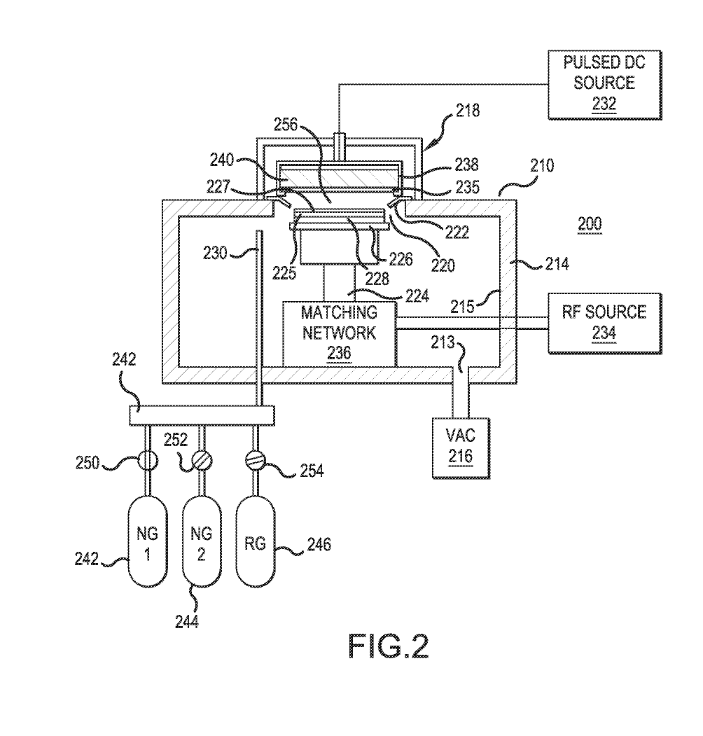

FIG. 2 is a simplified schematic drawing showing an example of a physical vapor deposition (PVD) system 200 that can be used to sputter deposit a piezoelectric layer in accordance with a representative embodiment. Notably, the PVD system 200 is merely illustrative and other types of PVD systems are known and are contemplated for use in connection with the present teachings. PVD system 200 comprises a reaction chamber 210 bounded by a wall 214, which comprises an inner surface 215. A vacuum pump 216 is in gas communication with reaction chamber 210 through an aperture 213 in watt 214. A target housing 218 is in gas communication with reaction chamber 210 through an aperture 220 in wall 214. An anode 222, which is illustratively annular, surrounds aperture 220. In the example shown, anode 222 is electrically connected to the wall 214 of reaction chamber 210, which serves as the system ground. A wafer lift 224 is located within reaction chamber 210 centered on aperture 220. A heating/cooling chuck 226 is mounted on wafer lift 224. Heating/cooling chuck 226 is thermally and electrically coupled to a wafer platform 228. A wafer 225 on which the piezoelectric layer is to be formed is placed on wafer platform 228 during the deposition method. The wafer platform 228 can be maintained at a negative voltage through application of power from the RF source 234 and can function as a secondary cathode.

The wafer 225 is an example of a substrate on which the piezoelectric layer can be deposited by the method disclosed herein. A gas inlet 230 extends through wall 214 to supply gases to reaction chamber 210. A pulsed DC source 232 is electrically connected between sputter cathode 238 and anode 222. An RF source 234 is electrically connected to wafer lift 224 and, hence, to wafer platform 228, via a matching network 236. Target housing 218 includes a sputter cathode 238 that holds a sputtering target 235 in a position such that the major surface of the target is substantially parallel to wafer platform 228. A magnet system 240 is located between sputter cathode 238 and sputtering target 235. The magnet system 240 generates magnetic fields that direct plasma formed in the reaction chamber 210 toward the target 235.

Gas inlet 230 is coupled to a manifold 242 to which are connected a gas source 244 of an inert gas, (illustratively a noble gas), and a gas source 246 of a reaction gas. Each gas source 244 and 246 is coupled to manifold 242 via a respective mass flow controller 250 and 254. Mass flow controllers 250 and 254 control the respective flow rates at which the noble gas and the reaction gas, respectively, are supplied to reaction chamber 210. In particular, mass flow controller 250 controls the flow rate of the noble gas. A plasma is created from the inert gas in the reaction chamber 210, and the plasma sputters atoms from the sputtering target 235. The reaction gas reacts with target material ejected from sputtering target 235 to form a piezoelectric layer 227 that is deposited on wafer 225.

FIG. 2 shows piezoelectric layer 227 deposited on the major surface of wafer 225 facing sputtering target 235. In the example shown, the piezoelectric layer 227 is aluminum nitride (AlN) doped with scandium (Sc), and nitrogen gas (N₂) is supplied to reaction chamber 210 as the reaction gas. In another example, the piezoelectric layer 227 is zinc oxide (ZnO) doped with magnesium (Mg) and oxygen gas (O₂) is supplied to reaction chamber 210 as the reaction gas. It is emphasized that these materials are merely illustrative, and other materials are contemplated. Some additional illustrative materials are disclosed below.

In operation of PVD system 200, wafer lift 224 is lowered to its lowest position and wafer 225 is placed on wafer platform 28. Wafer 225 is an example of a substrate on which a piezoelectric layer 227 is deposited. If no sputtering target has previously been installed, sputtering target 235 is installed in the target housing 218. Wafer lift 224 is then operated to raise wafer 225 into position adjacent anode 222, where the wafer 225 is separated from sputtering target 235 by gap 256. Heating/cooling chuck 226 is operated to set wafer 225 to a defined deposition temperature. In an example, the deposition temperature is 200° C. Vacuum pump 216 is operated to reduce the pressure within reaction chamber 210 to the working pressure of the deposition method, and the noble gas is supplied to the process chamber from gas source 244 via mass flow controller 250 manifold 242 and gas inlet 230. A reaction gas is additionally supplied to react on chamber 210 from gas source 246 via mass flow controller 254, manifold 242, and gas inlet 230.

In an example in which the piezoelectric material comprises aluminum nitride, the noble gas and the reaction gas supplied to reaction chamber 210 from gas sources 244 and 246 via mass flow controllers 250 and 254, manifold 242, and gas inlet 230 are argon (Ar) and nitrogen (N₂). Alternatively, krypton (Kr) may be used in place of or in addition to argon. The magnet system 240 generates a magnetic field in the gap 56 between sputtering target 235 and wafer 225. Magnet system 240 is structured to generate the magnetic field with field lines substantially orthogonal to the major surface of sputtering target 235.

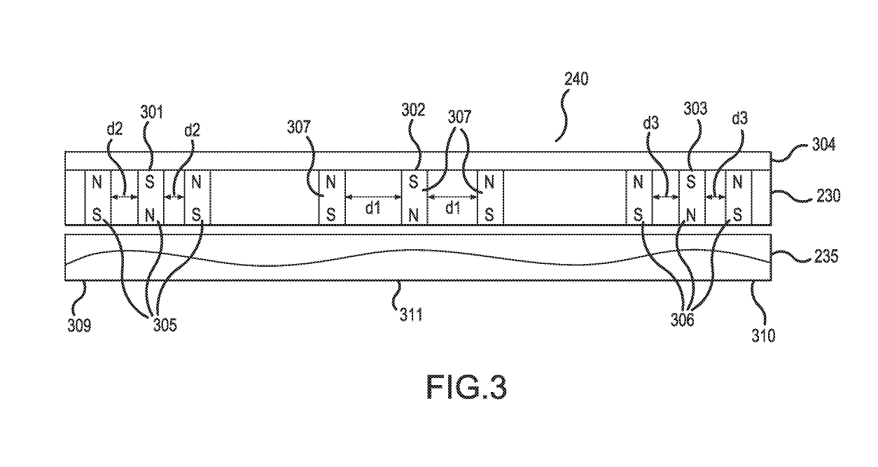

The magnet system 240 is configured to rotate during the sputtering process. The rotation of the magnet system 240 during sputtering fosters a more uniform deposition in the forming of the piezoelectric layer 227. The magnet system 240 is also configured to generate an enhanced magnetic field in the reaction chamber 210 running substantially parallel to a top surface of the sputtering target 235. As noted above, the magnetic field directs plasma formed in the reaction chamber 210 toward the target 235 to foster the deposition of sputtered material from the sputtering target 235 onto the wafer 225. As described more fully below, in the various embodiments, the magnet system 240 is configured to provide a slightly greater magnetic flux density towards the outer portions of the anode 222 and a slightly lesser magnetic flux density at the inner portion of the anode 222. Beneficially, by providing such a magnetic field orientation, the sputtering target 235 is fully eroded during sputtering. As used herein, and as described below in connection with FIG. 3, a “fully eroded” sputtering target 235 or “fill erosion” of the sputtering target 235 means that all portions of the surface of the sputtering target 235 facing or opposing the magnet system 240 are eroded, with some portions of the sputtering target 235 being eroded slightly more than others to produce improved thickness uniformity of the resultant piezoelectric layer 227. Notably, therefore, a fully eroded sputtering target does not have any significant portions on its surface facing the magnet system 240 that are not eroded during the sputtering process. Ultimately, this further improves the characteristics of the piezoelectric layer 227 formed over the wafer 225.

Pulsed DC source 232 applies DC power between sputtering target 235 and system ground (and, hence, anode 222). In a representative embodiment, the Pulsed DC power applied between the sputtering target 235 and the system ground is 9 W/cm¹ to approximately 21 W/cm², and in a specific embodiment, the Pulsed DC power applied is approximately 16 W/cm². Pulsed DC source 232 applies a DC voltage to sputter cathode 238 relative to system ground and, hence, anode 222 such that the sputter cathode 238 is at a negative voltage relative to the anode 222. A DC voltage that sets the sputter cathode 238 to a negative voltage relative to the anode will be referred to herein as a normal-polarity DC voltage. The normal-polarity DC voltage causes sputtering target 235 to emit electrons into the gap 256. In an example, the normal-polarity DC voltage is approximately 500 V. In response to the electric field generated by the normal-polarity DC voltage between sputter cathode 238 and anode 222, the electrons move towards wafer 225 in spirals around the magnetic field lines. The moving electrons collide with the gas atoms in the atmosphere within gap 256. The collisions dislodge electrons from the gas atoms, which converts the gas atoms into positively-charged gas ions. The electric field accelerates the gas ions towards sputtering target 235. The gas ions incident on sputtering target 235 eject target material from the target. The target material ejected from the target, referred to herein as ejected target material moves towards wafer 225 and a portion of the ejected target material is deposited on the wafer 225. While in transit to the wafer 225, and/or after it has been deposited on the wafer 225, the ejected target material reacts with the reaction gas constituting part of the atmosphere within gap 256 to form piezoelectric material on the major surface of wafer 225. Additionally, a small fraction of the noble gases constituting respective parts of the atmosphere within gap 256 may be trapped interstitially within the piezoelectric material.

A large positive charge that tends to repel the positively-charged gas ions accumulates on the sputtering target 235. To dissipate the accumulated positive charge, pulsed DC source 232 operates repetitively to turn off the DC voltage, to apply a smaller reverse-polarity DC voltage (e.g., about −50 V) between sputter cathode 238 and anode 222, and then to restore the normal-polarity DC voltage. In an example, the duration of the normal-polarity DC voltage is approximately 1 μs and the duration of the reverse-polarity DC voltage is approximately 100 ns. Other voltages and durations are possible and may be used. Additionally, the RE bias applied between wafer 225 and anode 222 applies a negative DC bias to the wafer 225 that attracts positively-charged ions to bombard the film of target material growing on the wafer 225 to control stress and enhance the mobility of arriving target material.

In another example, an additional RF source (not shown) is substituted for pulsed DC source 232, and material is transferred from sputtering target 235 to wafer 225 by RF sputter deposition. Other sputter deposition processes are known and may be used to transfer material from sputtering target 235 to wafer 225 by sputter deposition.

Deposition of the piezoelectric material continues until piezoelectric layer 227 reaches its specified thickness. During the deposition process, the RF bias applied between wafer 225 and anode 222 applies a negative DC bias to the wafer 225 that attracts positively-charged ions to bombard the film of target material growing on the wafer 225 to control stress and enhance the mobility of arriving target material. Wafer 225 with piezoelectric layer 227 on its major surface is then removed from reaction chamber 210 for further processing, including process operations that form electronic devices, such as BAW resonators, each having a respective portion of piezoelectric layer 227 as an element thereof. The method just described is then repeated to sputter deposit respective piezoelectric layers on additional wafers. Piezoelectric layers can be deposited on several wafers before all of the target material constituting sputtering target 235 is consumed. Once this occurs, the remains of sputtering target 235 are removed from target housing 218, and a new target is installed in the target holder.

The wafer 225 may be a chip or a wafer (to be subsequently separated into multiple chips). The wafer 225 may be formed of various materials, including materials compatible with semiconductor processes, such as silicon (Si), gallium arsenide (GaAs), indium phosphide (InP), or the like, which are useful for integrating connections and electronics. The sputtering target 235 likewise may be formed of various materials, depending on the desired composition of the resulting thin film.

In a representative embodiment, the sputtering target 235 may be a previously formed alloy of materials provided in the desired proportions. For example, the sputtering target 235 may be an alloy formed of aluminum and one or more of rare earth element(s) already cast in with the aluminum in the desired proportions to provide the desired atomic percentage of dopant in the resultant piezoelectric layer 227. In an alternative embodiment, the sputtering target 235 may be a composite sputtering target formed of a block of a base element containing inserts or plugs of doping element(s). For example, the doping element(s) may be introduced by drilling one or more holes in the base element and inserting plugs of the doping element(s) into the respective holes in the desired proportions. For example, the sputtering target 235 may be formed substantially of a block of aluminum as the base element, and plugs of doping elements (e.g., scandium, erbium, and/or yttrium) may be insertable into holes previously formed in the block of aluminum. The percentage of each of the doping element(s) in the finished thin film corresponds to the collective volume of that element inserted into one or more respective holes, which displaces a corresponding volume of the base element. Examples of doping with rare earth elements are provided by Grannen, et al. in U.S. patent application Ser. No. 13/662,460 (filed Oct. 27, 2012) and Bradley et al. in U.S. patent application Ser. No. 13/662,425 (filed Oct. 27, 2012), the entire contents of which are hereby incorporated by reference in their entireties.

The size and number of holes, as well as the amount and type of the doping element filling each of the holes, may be determined on a case-by-case basis, depending on the desired percentages of the doping elements. For example, the holes may be drilled partially or entirely through the base element of the sputtering target 235 in the desired sizes and numbers in various patterns. Similarly, in alternative embodiments, the dopants may be added to the base element of the sputtering target 235 in the desired proportions using various alternative types of insertions, without departing from the scope of the present teachings. For example, full or partial rings formed of the dopants, respectively, may be inlaid in the sputtering target 235. The number, width, depth and circumference of each ring may be adjusted to provide the desired proportion of each particular element. The structures and techniques for providing an appropriate sputtering target 235 truly vary to provide unique benefits for any particular situation or to meet application specific design requirements of various implementations, without departing from the scope of the present teachings, as would be apparent to one skilled in the art.

In accordance with representative embodiments, the sputtering target 235 may be formed entirely of a single element, or may be a composite or alloy formed of a base element with one or more doping elements (dopants). For example, if the desired composition of the thin film to be formed on the wafer 225 is aluminum nitride (AlN), where the nitrogen (N) is provided as a reaction gas included in the sputtering gas, the sputtering target 235 is formed entirely of aluminum (Al). If it is desired to sputter a thin film consisting of a compound of aluminum nitride (AlN) doped with a rare earth element, such as scandium (Sc), erbium (Er) or yttrium (Y), for example, the sputtering target 235 may be formed of aluminum and one or more rare earth elements in proportions substantially the same as those desired in the sputtered thin film.

Because the doping elements replace only the metal atoms of the sputtering target 235 (e.g., of an Al sputtering target), the percentage of nitrogen atoms in the piezoelectric layer 227 remains substantially the same regardless of the amount of doping. As such, when percentages of doping elements are discussed herein, it is in reference to the total atoms (not including nitrogen) of the AlN piezoelectric material, and is referred to herein as “atomic percentage.” Moreover, the atomic percentage of the doping element in the piezoelectric layer 227 is substantially the same as the atomic percentage of the doping element in the composite or alloy of the sputtering target 235.

In certain embodiments the piezoelectric layer 227 comprises aluminum nitride (AlN) that is doped with scandium (Sc). The atomic percentage of scandium in an aluminum nitride layer is approximately 0.5% to less than approximately 10.0%. More generally, the atomic percentage of scandium in the piezoelectric layer 227 comprising an aluminum nitride layer is approximately 0.5% to approximately 44% in certain embodiments. In yet other representative embodiments, the atomic percentage of scandium in an aluminum nitride layer is approximately 2.5% to less than approximately 5.0%. When percentages of doping elements in a piezoelectric layer are discussed herein, it is in reference to the total atoms of the piezoelectric layer. Notably, when the percentage of doping elements (e.g., Sc) in a doped AlN layer are discussed herein, it is in reference to the total atoms (not including nitrogen) of the AlN piezoelectric layer 227. So, for example, and as described for example in U.S. patent application Ser. No. 14/161,564, if the Al in the piezoelectric layer of a representative embodiment has an atomic percentage of approximately 95.0%, and the Sc has an atomic percentage of approximately 5.0%, then atomic consistency of the piezoelectric layer 104 may be represented as Al_{0.95}Sc_{0.05}N.

It is noted that the use of scandium as the doping element is merely illustrative, and other rare-earth elements are contemplated for use as the doping element of the piezoelectric layer 227. Notably, other rare-earth elements including yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb) and lutetium (Lu), as known by one of ordinary skill in the art. The various embodiments contemplate incorporation of any one or more rare-earth elements, although specific examples are discussed herein.

The sputtering target 235 of the representative embodiments has characteristics that foster the fabrication of piezoelectric layer 227 that is highly textured, with a well oriented c-axis, and that has a comparatively low defect density. For example, in an alloy sputtering target, intermetallic (second phase) compounds can be formed during the fabrication of the sputtering target sputtering target 235). These intermetailic compounds form precipitates in the sputtering target 235, which can result in non-uniform deposition of the doping element in the piezoelectric layer 227. For example, in an embodiment in which piezoelectric layer 227 comprises ScAlN, the sputtering target 235 comprises a Sc—Al alloy with atomic percentages of scandium and aluminum selected to provide the desired doping level of scandium in the piezoelectric layer 227, which is illustratively AlScN. Sc—Al intermetallic precipitates (e.g., ScAl₃) act like “hot spots” in the sputtering target 235 that are sputtered over the wafer 225 and result in defects in the crystalline structure. These defects create non-uniformities in the piezoelectric layer 227 that undesirably can impact the characteristics of the material of the piezoelectric layer. Most notably, these non-uniformities in the piezoelectric layer 227 can result in undesired variation in tensile stress and the electromechanical coupling coefficient kt². As can be appreciated, the larger the grain size of the scandium aluminum alloy, particularly the second phase, ScAl₃, the more deleterious their impact can be on the piezoelectric layer 227. As such, in accordance with a representative embodiment, the grain size of the intermetallic precipitates, which are scandium aluminum alloy precipitates (e.g., ScAl₃) in this example, is less than approximately 100 μm, and preferably less than approximately 40 μm, and as small as 3 μm.

Another source of defects in the piezoelectric layer 227 can be microcracks, or voids, or both, in the sputtering target 235. These microcracks and voids are susceptible to electrostatic arcing during the application of the DC voltage between the anode 222 and the sputter cathode 238. This electrostatic arcing can produce a molten material formed from the components of the sputtering target 235. This molten material can fall on the wafer 225, the piezoelectric layer 227, and elsewhere in the reaction chamber 210 (e.g., on the inner surface 215) forming macroscopic particles of the material. These macroscopic particles can fall directly, or can fall from elsewhere in the reaction chamber 210 during sputtering, and ultimately land on the piezoelectric layer 227, or on the piezoelectric layer 227 during its formation, or both. As can be appreciated, these macroscopic particles create undesired interruptions in the crystalline growth of the piezoelectric layer 227, and ultimately, degrade the crystalline orientation of the resultant material. Ultimately, this can result in reduction in the quality/texture of the piezoelectric layer 227. Applicants have discovered that minimizing the maximum size of the microcracks and voids in the sputtering target 235 significantly reduces the severity of electrostatic arcing, and consequently, reduces the degree of formation of molten material both on the wafer 225 and piezoelectric layer 227, and elsewhere in the reaction chamber 210. Notably, in accordance with a representative embodiment, the sputtering target 235 has microcracks, or voids, or both, having a target density of 98% or greater of the theoretical density, where the theoretical density of the alloy of the sputtering target 235 is the density of a “perfect alloy” of the materials that make up the sputtering target 235 at their particular proportions. For example, the theoretical density of a sputtering target having 5% scandium and 95% aluminum can be calculated using their atomic masses by known methods. A target having a target density of 98% of the calculated theoretical density would have the lesser density due to voids and microcracks formed during fabrication of the sputtering target 235. Alternatively, the microcracks, or voids, or both beneficially have a grain size of less than approximately 100 μm to approximately 3 μm. Furthermore, the density of defects due to microcracks and voids in the sputtering target 235 is made comparatively low: approximately 2 defects/cm². As a result of limiting the size of the microcracks and voids in the sputtering target 235, the piezoelectric layer 227 formed in accordance with the representative embodiments is a high quality crystalline material and a highly textured piezoelectric layer having characteristics of such a material described herein.

Among other beneficial aspects of the present teachings, the characteristics of the sputtering target 235 and the magnet system 240 (described in more detail below) of representative embodiments described above and below foster the formation of piezoelectric layer 227 comprising a high quality crystalline material, which is highly textured and has a tensile stress across the piezoelectric layer 227 that is comparatively uniform, resulting in a comparatively uniform electromechanical coupling coefficient kt² across the piezoelectric layer 227. For example, in one representative embodiment, the piezoelectric layer 227 is ScAlN and has a 1.54° rocking curve full width at half maximum crystalline orientation distribution, which is indicative of a highly textured (highly aligned c-axis) piezoelectric material. Moreover, the tensile stress of piezoelectric layer 227 in this representative embodiment is approximately 24.5 MPa, with a standard deviation of approximately 13.4 MPa across the piezoelectric layer 227. As should be appreciated by one of ordinary skill in the art, a standard deviation of the tensile stress of this magnitude is indicative of a comparatively uniform tensile stress across the piezoelectric layer 227. More generally, the stress of the piezoelectric layer 227 is approximately −150 MPa to approximately 250 MPa, with a standard deviation of approximately 0 MPa to approximately 50 MPa. Furthermore, because the electromechanical coupling coefficient kt² is related to the tensile stress, the electromechanical coupling coefficient kt² is beneficially also comparatively uniform across the piezoelectric layer 227. Illustratively, the electromechanical coupling coefficient kt² varies approximately 0.07%/100 MPa.

FIG. 3 is a cross-sectional view of magnet system 240 shown in FIG. 2 for use in a magnet system sputtering device for depositing a thin film of a material on wafer 225 from sputtering target 235, according to a representative embodiment. The magnet system 240 comprises north (N)/south (S) pole arrangements at outer portions 301, 303 (i.e., near the edges of the magnet system 240) connected to pole piece 304 at the outer portions of the anode (not shown in FIG. 3), and the oppositely polarized S/N pole arrangement at the inner portion 302 connected to pole piece 304 at an inner portion of the anode (not shown in FIG. 3). The NS pole arrangements at the outer portions 301 and 303, comprise multiple magnets 305 and multiple magnets 306, respectively, while the N/S pole arrangement at the inner portion 302 comprises multiple magnets 307. In the depicted embodiment, the magnet system 240 is substantially circular in shape, with an overall substantially planar profile.

As depicted in FIG. 3, the multiple magnets 307 of the inner portion 302 of the magnet system 240 are spaced a distance d₁ apart, whereas multiple magnets 305 and 306 are spaced apart by distances d₂and d₃, respectively. In a representative embodiment, d₂ is approximately equal in magnitude to d₃, although this is not essential. Notably, however distance d₁ is greater than both d₂, and d₃. By spacing multiple magnets 307 farther apart than both d₂ and d₃, the magnetic flux density of the magnet system 240 is slightly less at the inner portion 302 than at the outer portions 301 and 303 of the magnet system 240.

By providing a somewhat slightly lower magnetic flux density at the inner portion 302 of the magnet system 240 relative to the magnetic flux densities at the outer portions 301 and 303 according to a representative embodiment, a comparatively complete erosion profile 308 of the sputtering target 235 is realized compared to the erosion profile of a sputtering target using a known magnet system and fabrication sequence. Most notably, at the outer portions 309 and 310 of the sputtering target 235, the erosion profile 308 is substantially complete and uniform, with substantially the same degree of erosion as the erosion profile at the inner portion 311 of the sputtering target 235. As noted above, fill erosion of the sputtering target 235 means that all portions across the surface of the target are eroded, with some portions of the sputtering target 235 being eroded slightly more than others to produce improved thickness uniformity of the resultant piezoelectric layer 227. This full erosion of the sputtering target 235 can be seen readily from a review of the erosion profile 308. Most notably, unlike known erosion profiles, as a result of the methods and apparatuses of the present teachings, there are no “uneroded” portions of the sputtering target 235, but rather full erosion across the surface of the sputtering target 235.

Because the erosion of the sputtering target 235 is substantially uniform and complete across its area, certain benefits are realized in the piezoelectric layer 227 fabricated with the magnet system 240 of the representative embodiments. First, the resultant piezoelectric layer 227 has a substantially uniform thickness over its area. For example, the standard deviation of the thickness per mean thickness of the piezoelectric layer 227, which comprises scandium doped aluminum nitride, is less than approximately 1.0%. In another representative embodiment, the center-to-edge thickness variation across the piezoelectric layer 227 is less than approximately 0.02%. As such, by this example, an 8000 Å thick ScAlN film formed using the apparatus and methods of a representative embodiment has a center-to-edge thickness difference that is than approximately 150 Å. By contrast, the standard deviation of the thickness per mean thickness for a scandium doped aluminum nitride layer, which is fabricated by a known method and using a known apparatus, and has the same atomic percentage of scandium as the scandium doped aluminum nitride fabricated in accordance with the apparatus and method of the representative embodiment, is approximately 8% to approximately 12%. As can be appreciated by one of ordinary skill in the art, a reduced standard deviation/variation in the center-to-edge thickness of the piezoelectric layer 227 results in a significant improvement in device performance and consistency of performance from one device to the next.

Moreover, the substantially uniform and complete erosion of the sputtering target 235 across its width reduces the build up of backscattered sputtered target material at the outer portions 309 and 310 of the sputtering target 235. To this end, when material in the outer portions 309, 310 is not eroded or is insignificantly eroded compared to other portions of the sputtering target 235, particles from these regions of the sputtering target 235 can detach from the sputtering target 235. These particles fall from the sputtering target 235 and land on portions of the reaction chamber 210, such as on the inner surface 215. These particles can also deposit on the wafer 225 or on the piezoelectric layer 227, or both, and result in dopant (e.g., Sc) rich material in the piezoelectric layer 227. As can be appreciated, among other undesired results, these particles can adversely impact the quality of the crystalline structure of the piezoelectric layer 227, as well as the orientation of the c-axis (texture) of the piezoelectric layer 227. Moreover, in flight, these particles can serve as local nodes for electrostatic arcing, which results in the deposition of molten material on the wafer 225 or on the piezoelectric layer 227, or both, resulting in the deleterious interruption of the formation of the crystal. Because of the full erosion of the sputtering target 235 realized by use of the magnet system 240 of representative embodiments, in methods according to representative embodiments, the formation of these undesired particles is substantially reduced, which contributes to the formation of piezoelectric layer 227 comprising a high quality crystalline material, which is highly textured, and has a tensile stress across the piezoelectric layer that is comparatively uniform, resulting in a comparatively uniform electromechanical coupling coefficient kt² across the piezoelectric layer 227.

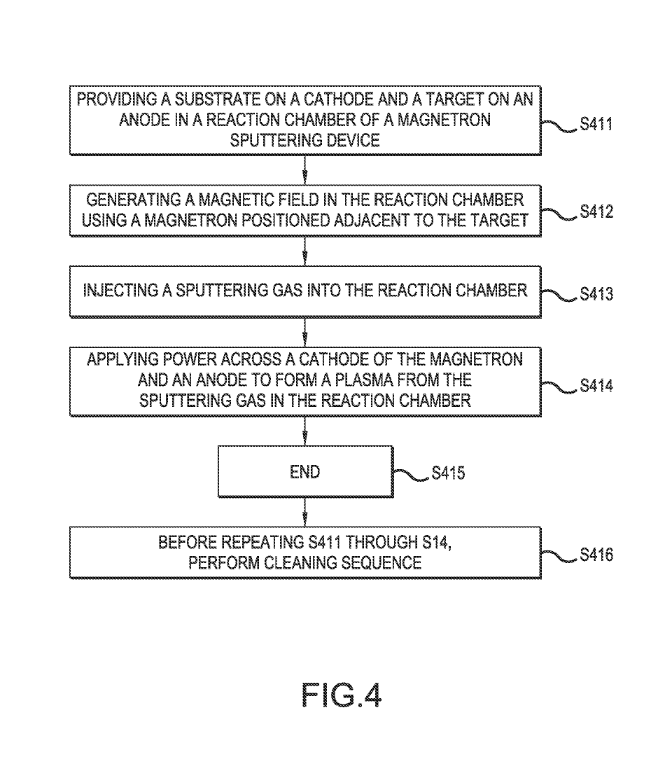

FIG. 4 is a flow diagram showing a method of depositing a thin film of compound material on a substrate using sputter deposition, according to a representative embodiment. Referring to FIG. 4, various items required for depositing a thin film of compound material on a substrate using a PVD system (e.g., PVD system 200) are provided in block S411. For example, wafer 225 may be applied to sputter cathode 238 and sputtering target 235 may be applied to anode 222 in reaction chamber 210 of PVD system 200. As discussed above, the sputtering target 235 may be a single element (e.g., aluminum) or a combination of elements (e.g., aluminum doped with one or more rare earth elements, such as scandium, erbium and yttrium) already cast in with the aluminum in the desired proportions to provide the desired atomic percentage of dopant in the resultant piezoelectric layer 227. For example, the sputtering target 235 may be a preformed alloy of aluminum and scandium in desired proportions. Alternatively, the sputtering target 235 may be a block of aluminum having at least one hole into which one or more plugs of at least one rare earth element are insertable. The amount of aluminum in the aluminum block and the total amount of rare earth element(s) inserted as plug(s) into the aluminum block are provided in the desired proportions.

In block S412, a magnetic field is generated in the reaction chamber 210, for example, using magnet system 240 of the PVD system 200. As noted above, the magnetic field directs plasma formed in the reaction chamber 210 toward the target 235 to foster the deposition of sputtered material from the sputtering target 235 onto the wafer 225. The magnet system 240 provides an increased magnetic flux density at the outer portions than at the inner portion of the magnet system 240 as discussed above. In an embodiment, the magnetic field at the outer portions has a magnetic flux density in the range of approximately 1000 Gauss to approximately 100 Gauss for example. In comparison, the magnetic field at the inner portion has a magnetic flux density of 50 Gauss to approximately 800 Gauss, for example. Moreover, as noted above, the sputtering target 235 is substantially fully eroded.

Sputtering gas is injected into the reaction chamber 210 at low pressure in block S413. For example, the sputtering gas may be maintained at a pressure of about 1 mTorr to about 20 mTorr in the reaction chamber 210. As discussed above, the sputtering gas contained in the reaction chamber 210 may include noble gas from gas source 244, or noble gas from gas source 244 combined with reaction gas (e.g., nitrogen) from gas source 246. In the latter scenario, at least a portion of the reaction gas is deposited on the wafer 225 along with the at least one element from the sputtering target 235 for forming the thin film of the compound material on the wafer 225.

In block S414, power is applied across e sputter cathode 238 and the anode 222 of the PVD system 200 to create plasma from the sputtering gas injected into the reaction chamber 210 in block S413. The plasma comprises ions that bombard the sputtering target 235, causing atoms of at least one element (along with electrons) to be ejected from the sputtering target 235. At least some of the ejected atoms are sputtered onto the wafer 225 to form the thin film of the compound material. The power applied across the sputter cathode 238 and the anode 222 of the PVD system 200 is enhanced over power applied in a conventional method, in that the power density of the power applied across the sputtering target 235 and the anode 222 is in a range of about 9 W/cm² to approximately 21 W/cm².

The magnetic field generated in block S412 generally runs substantially parallel to the top surface of the sputtering target 235. Accordingly, electrons ejected from the sputtering target 235 in response to the ion bombardment are held close to the surface of the sputtering target 235 by the magnetic field generated by magnet system 240. The presence of these trapped electrons generally increases and the plasma density improves sputter deposition rates, as mentioned above.

Among other noted improvements in the characteristics of the piezoelectric layer 227 fabricated according to the methods and using the apparatuses of the representative embodiments, are the improvements in the magnitude and uniformity of the stress across the piezoelectric layer 227. In an experiment performed for purposes of illustration, a known magnet system sputtering process for providing an ScAlN thin film (with about 5 atomic percent scandium) produced a cross-wafer thin film stress range of approximately −750 MPa to approximately −200 MPa, where negative stress values are compressive stress and positive stress values are tensile. By contrast, the sputtering process for providing an ScAlN thin film (with about 5 atomic percent scandium), using the methods and apparatuses according to representative embodiments, produced a cross-wafer thin film stress range of in the range of approximately −100 MPa to approximately +150 MPa. Beneficially, the overall average thin film stress and the thin film stress range are reduced. Furthermore, the standard deviation of the stress of a piezoelectric layer fabricated according to the known method and using the known apparatus is approximately 100 MPa to approximately 150 MPa. By contrast, the standard deviation of the stress of a piezoelectric layer 227 fabricated according to the method and using the apparatus according to representative embodiments is approximately 12 MPa to approximately 50 MPa.

As discussed above, due to dependence of the electromechanical coupling coefficient kt² on the observed thin film stress, the spread of the electromechanical coupling coefficient kt² (coupling coefficient spread) across the wafer is reduced when apparatuses and methods according to representative embodiments, as compared to known magnetic sputtering processes and apparatuses. Notably, the variation in kt²over a known piezoelectric layer is approximately 0.15% to approximately 0.25%. By contrast, the variation in kt² over piezoelectric layer 227 fabricated by the methods and apparatuses according to representative embodiments is approximately 0.03% to approximately 0.07%.

After completion of the steps in block S414, the method terminates at block S415. The wafer 225 is then removed from the reaction chamber 210, and further processing continues elsewhere to fabrication devices (e.g., FBARs and filters comprising FBARs) according to methods noted above.

According to a representative embodiment, and prior to the introduction of another substrate into the reaction chamber 210, a cleaning step noted in block S415 is effected. This cleaning step comprises providing another substrate (e.g., a “dummy” wafer) in the reaction chamber 210, and sputtering atoms from the sputtering target 235 in a manner substantially the same as is used to fabricate piezoelectric layer 227 over the wafer 225, with the significant exception that the reaction gas (e.g., nitrogen) is not flowed. As such, rather than sputtering the metal from the sputtering target 235 to react with the reaction gas to form piezoelectric layer 227, only sputtered metal atoms are provided in the reaction chamber 210. These metal atoms deposit not only on the substrate, but also on other surfaces of the reaction chamber 210. Among other things, the sputter metal from the sputtering target 235 tends to “adhere” the flaking particles to the various surfaces of the reaction chamber 210, thereby preventing their failing from the sputtering target 235 onto other surfaces. As noted above, these flaking particles can comprise dopant-rich intermetallic particles formed during the sputtering sequence. If not adhered, during subsequent sputtering, these particles can drop onto the wafer 225 and piezoelectric layer 227, which can lead to defects in the resultant piezoelectric layer 227. Moreover, during their fall from in the reaction chamber 210, these particles can serves as nodes for electrostatic arcing and the formation of undesired molten particles.

Finally, and among other benefits, the cleaning step serves to cover or coat the anode 222 with a layer of metal. Notably, during sputter deposition, the piezoelectric material (e.g., AlN or ScAlN) deposits in various locations inside the reaction chamber 210, including the anode 222 and inner surface(s) 215 of the reaction chamber. As these materials are dielectrics, the anode can be compromised, and the voltage difference between the sputter cathode 238 and the anode 222 (or inner surface(s) 215) can be increased by the layer of dielectric. Accordingly, the sputtering of the metal from the sputtering target 235 tends to reform the anode 222 which reduces the voltage differences which reduces the tendency to arc.

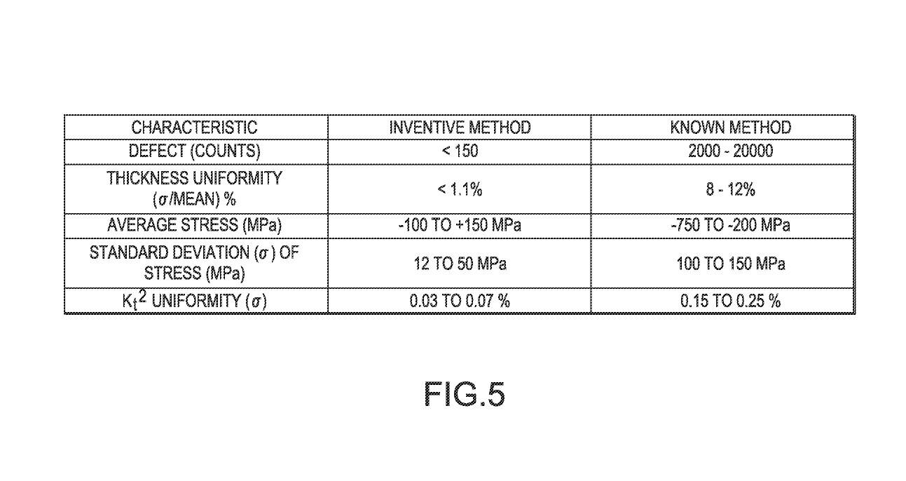

FIG. 5 is a table comparing various useful characteristics of piezoelectric layer 227 fabricated according to the methods and using apparatuses in accordance with representative embodiments, to a piezoelectric layer formed using known methods and apparatuses. Notably, many of the benefits of improvements in these characteristics discussed above and often are not repeated presently, namely cross-wafer stress and the electromechanical coupling coefficients kt² of a thin film deposited on a substrate using a PVD system, according to representative embodiments.

Referring to FIG. 5, it is clear that the defects in the piezoelectric layer 227 are significantly lower than those found in the known piezoelectric layer. By reducing the defects in the piezoelectric layer 227 the crystalline structure of the material is substantially improved and results in improvements in the quality of the piezoelectric layer 227 and results in a highly textured (material with a highly oriented c-axis) material. Furthermore, as noted above, the reduction in defects also enhances the reliability of the devices fabricated with the piezoelectric layer 227 of the representative embodiments.

Similarly, the uniformity in the thickness of the piezoelectric layer 27 is significantly better when compared to that of the known piezoelectric layer. As noted above, this uniformity in thickness begets improvements in operating characteristics of devices incorporating the piezoelectric layer 227, and more consistent operating characteristics from device to device across the wafer 225.

As noted above, the average stress and the variation in the stress across the piezoelectric layer 227 formed using the methods and apparatuses of representative embodiments are both significantly improved when compared to the average stress and variation in the stress of a known piezoelectric layer fabricated using known methods and apparatuses. Furthermore, the reduced variation in stress across piezoelectric layer 227 results in a reduced variation in the electromechanical coupling coefficient kt² (coupling coefficient spread) across the piezoelectric layer 227 when fabricated according to apparatuses of representative embodiments, as compared to known magnetic sputtering processes and apparatuses.

In alternative embodiments, piezoelectric thin films doped with one or more rare earth elements may be sputtered in resonator stacks of various other types of resonator devices, without departing from the scope of the present teachings. For example, a piezoelectric layer doped with one or more rare earth elements may be sputtered in resonator stacks of a solidly mounted resonator (SMR) device, a stacked bulk acoustic resonator (SBAR) device, a double bulk acoustic resonator (DBAR) device, or a coupled resonator filter (CRF) device.

One of ordinary skill in the art would appreciate that many variations that are in accordance with the present teachings are possible and remain within the scope of the appended claims. These and other variations would become clear to one of ordinary skill in the art after inspection of the specification, drawings and claims herein. The invention therefore is not to be restricted except within the spirit and scope of the appended claims.

1. A plasma vapor deposition (PVD) system for depositing a piezoelectric layer over a substrate, the PVD system comprising:
a reaction chamber configured to contain the substrate, a sputtering target, a sputtering gas and a plasma; and
a magnet system positioned adjacent the sputtering target and configured to generate a magnetic field in the reaction chamber, the magnet system configured to generate a magnetic field pattern having a greater magnetic flux density at outer portions of the magnet system than at an inner portion of the magnet system, wherein the plasma sputters atoms from the sputtering target, which are deposited on the substrate for forming the piezoelectric layer.

2. The system of claim 1, wherein a power density of the power applied across the sputtering target and the anode is in a range of approximately 9 W/cm² to about 21 W/cm².

3. The system of claim 1, wherein the power density of the power applied across the sputtering target and the anode is approximately 16 W/cm2.

4. The system of claim 1, wherein a magnitude of the magnetic flux density at the inner portion of the magnet system is in a range of approximately 50 Gauss to approximately 800 Gauss.

5. The system of claim 1, wherein a magnitude of the magnetic flux density at the outer portions of the magnet system is in the range of approximately 100 Gauss to approximately 1000 Gauss.

6. The system of claim 5, wherein the inert gas is a noble gas, the reaction gas is nitrogen or oxygen.

7. The system of claim 6, wherein the sputtering target comprises aluminum and at least one rare earth element.

8. The system of claim 7, wherein the least one rare earth element is scandium.

9. The system of claim 1, wherein the sputtering target is an alloy of aluminum and scandium.

10. The system of claim 9, wherein the alloy comprises a secondary phase Al—Sc precipitates having a maximum grain size in the range of less than approximately 100 μm to approximately 3 μm.

11. The system of claim 9, wherein the alloy has a density of greater than 98% of a theoretical density of the alloy.

12. The system of claim 9, wherein the alloy comprises voids, or microcracks, or both, each having a maximum grain size of less than approximately 100 μm to approximately 3 μm.

13. The system of claim 9, wherein the sputtering target is substantially evenly eroded across a surface opposing the magnet system.

14. The system of claim 7, wherein a piezoelectric layer is formed over the substrate, the piezoelectric layer comprising highly textured aluminum nitride material doped with a rare-earth element.

15. The system of claim 14, wherein the rare-earth element is Scandium and the piezoelectric layer has a tensile stress having a standard deviation of approximately 14 MPa across the piezoelectric layer.

16. The system of claim 14, wherein the rare-earth element is Scandium, and the piezoelectric layer has a 1.54° Rocking curve scan crystalline orientation distribution.

17. A method of forming a piezoelectric layer over a substrate using sputter deposition, the method comprising:
providing the substrate and a sputtering target on in a reaction chamber of a plasma vapor deposition (PVD) system, the sputtering target comprising aluminum and at least one rare earth element;
generating a magnetic field in the reaction chamber using a magnet system positioned adjacent the sputtering target, the magnetic field pattern having a greater magnetic flux density at outer portions of the magnet system than at an inner portion of the magnet system;
injecting a sputtering gas into the reaction chamber; and
forming a plasma from the sputtering gas in the reaction chamber, the plasma sputtering atoms from the sputtering target, which are deposited on the substrate for forming the thin film of the material.

18. The method of claim 17, wherein a power density of the power applied across the anode and the cathode is in a range of approximately 9 W/cm² to approximately 21 W/cm².

19. The method of claim 17, wherein the magnetic flux density at the inner portion of the magnet system is in a range of approximately 50 Gauss to approximately 800 Gauss.

20. The method of claim 17, wherein the magnetic flux density at the outer portions of the magnet system is in a range of approximately 100 Gauss to approximately 1000 Gauss.

21. The method of claim 20, wherein the inert gas is argon or krypton, or both, and the reaction gas in nitrogen.

22. The method of claim 20, wherein the sputtering target comprises aluminum and at least one rare earth element.

23. The method of claim 22, wherein the least one rare earth element is scandium.

24. The method of claim 17, wherein the sputtering target is a composite or an alloy of aluminum and scandium.

25. The method of claim 24, wherein the composite or alloy comprises secondary phase Al—Sc precipitates having a maximum grain size in the range of less than approximately 100 μm to approximately 3 μm.

26. The method of claim 25, wherein the alloy has a density of approximately 98% of a theoretical density of the alloy.

27. The method of claim 25, wherein the alloy comprises voids, or microcracks, or both, each having a maximum grain size of less than approximately 100 μm to approximately 3 μm.

28. The method of claim 17, further comprising substantially evenly eroding the sputtering target across a surface opposing the magnet system.

29. The method of claim 17, wherein a piezoelectric layer is formed over the substrate, the piezoelectric layer comprising highly textured aluminum nitride material doped with a rare-earth element.

30. The method of claim 29, wherein the rare-earth element is Scandium, and the piezoelectric layer has a tensile stress having a standard deviation of approximately 14 MPa across the piezoelectric layer.

31. The method of claim 29, wherein the rare-earth element is Scandium, and the piezoelectric layer has a 1.54° Rocking curve scan crystalline orientation distribution.

32. The method of claim 17, wherein the sputtering gas comprises an inert gas and a reaction gas, a least a portion of the reaction gas being deposited on the substrate along with the at least one element from the sputtering target for forming the thin film of the material.

33. The method of claim 16, further comprising:
after the deposition of the plasma sputtering atoms over the substrate is complete, removing the substrate having a piezoelectric layer formed thereover;
providing a second substrate in the reaction chamber;
generating the magnetic field in the reaction chamber using a magnet system positioned adjacent the sputtering target and configured to generate a magnetic field in the reaction chamber, the magnetic field pattern having an equal or greater magnetic flux density at outer portions of the magnet system than at an inner portion of the magnet system;
forming a plasma, but not flowing a reaction gas while the second substrate is provided in the reaction chamber; and
sputtering metal elements from the sputtering target form the anode over an inner surface of the reaction chamber.

34. The method of claim 3, wherein the plasma comprises argon, or krypton, or both, and nitrogen.

35. The method of claim 33, wherein the anode reformed over the inner surface of the reaction chamber comprises forming a metal layer comprising the atoms of the sputtering target.

36. The method as claimed in claim 35, wherein the atoms of e sputtering target comprise aluminum and a rare-earth element.

37. The method as claimed in claim 36, wherein the rare-earth element comprises scandium.
